(19) United States
(12) Patent Application Publication
(10) Pub. No.: US 2013/0257427 A1
(43) Pub. Date: Oct. 3, 2013

(54) Determining a Magnetic Resonance System Control Sequence

(71) Applicants: Hans-Peter Fautz, Forchheim (DE); Rene Gumbrecht, Herzogenaurach (DE)

(72) Inventors: Hans-Peter Fautz, Forchheim (DE); Rene Gumbrecht, Herzogenaurach (DE)

(21) Appl. No.: 13/854,064

(22) Filed: Mar. 30, 2013

(30) Foreign Application Priority Data
Mar. 30, 2012 (DE) DE 102012205297.6

(51) Int. Cl. G01R 33/54

(52) U.S. Cl. CPC G01R 33/543
USPC 324/309; 324/318

(57) ABSTRACT

A method and a control sequence determination device are provided for determining a magnetic resonance control sequence that includes a multichannel pulse train with a number of individual RF pulse trains sent out in parallel by a magnetic resonance system over different independent radio-frequency transmit channels. The multichannel pulse train is calculated based on a predetermined target function with a predetermined target magnetization in an RF pulse optimization method. The RF pulse optimization method takes account of the magnetization in the form of a non-linear equation and of a local radio-frequency load and in a plurality of volume elements in the form of quadratic equation systems.

This application claims the benefit of DE 10 2012 205 297.6, filed on Mar. 30, 2012, which is hereby incorporated by reference.

### BACKGROUND

The present embodiments relate to a method and a control sequence determination device for determining a magnetic resonance system control sequence.

In a magnetic resonance system, a body to be examined may be exposed with the aid of a basic field magnet system to a relatively high basic field magnetic field (e.g., of 3 or 7 Tesla). In addition, a magnetic field gradient is applied with the aid of a gradient system. Radio-frequency excitation signals (RF signals) are then transmitted by suitable antenna devices via a radio-frequency transmit system that is intended to lead to the nuclear spin of specific atoms resonantly excited by this radio frequency field being flipped locally-resolved by a defined flip angle in relation to the magnetic field lines of the basic magnetic field. This radio-frequency excitation or the resulting flip angle distribution is also referred to below as core magnetization or “magnetization”. During the relaxation of the nuclear spin radio-frequency signals, magnetic resonance signals are emitted, which are received by suitable receive antennas and are further processed. The desired image data may be reconstructed from the raw data thus acquired.

The radio-frequency signals for nuclear spin magnetization are sent out by a whole body coil or body coil or also with local coils placed on the patient or object under examination. With high basic magnetic fields of for example 7 Tesla, local coils may be used. A structure of a whole body coil may be a birdcage antenna that includes a number of send rods that are disposed running in parallel to the longitudinal axis around a patient chamber of the tomograph, in which a patient is located during examination. The antenna rods are capacitively connected to each other on an end face side in the form of a ring in each case.

With magnetic resonance systems, a single temporal RF signal may be issued to all components of the transmit antenna (e.g., to all send rods of a birdcage antenna). This may be referred to as “CP mode”, with CP standing for circular polarized. In this case, the pulses may be transferred phase-offset to the individual component, with a shift matched to the geometry of the send coil. For example, with a birdcage antenna with 16 rods, the rods may each be controlled with the same RF magnitude signal with 22.5% phase offset. Such an excitation leads to a radio-frequency load on the patient that is to be restricted in accordance with the usual rules, since too great a radio-frequency load may result in injuries to the patient. The IEC standard, for example, basically prescribes for the local coils typical for 7 Tesla a limitation of the local specific absorption rate (SAR). For an excitation in “CP mode,” the phase angle is known in advance, and thus, the local SAR load may be determined by scaling the globally accepted RF power by a factor. The global RF power is thus measured, but the local load is monitored via the factor and the known phase difference of the RF pulses.

With magnetic resonance systems, individual RF signals matched to the respective image output may be assigned to the individual transmit channels (e.g., the individual rods of a birdcage antenna). For this purpose, a multi-channel pulse train that includes a number of individual radio-frequency pulse trains that may be transmitted in parallel over the different independent radio-frequency transmit channels is transmitted. Such a multi-channel pulse train (e.g., on account of the parallel transmission of the individual pulses, the “pTX pulse”) may, for example, be used as an excitation, refocusing or inversion pulse.

During sending out of multi-channel pulse trains, in the measurement tunnel and consequently also in the patient, the previous excitation form may be replaced by any given excitation form. In such cases, the result may be overlaying effects of the electrical fields of the individual transmit channels and embodiment of hotspots at which a far greater radio-frequency load forms. This may amount to a multiple of the previous values known from typical excitations. To estimate the maximum radio-frequency load, any given radio-frequency overlaying is therefore to be investigated. The “simple” scaling factor explained above, which scales the values of the global load into a local load, no longer leads with a pTX pulse to acceptable results. A complex dependency on the phase relationships of the pTX pulse is produced. This may be investigated in a simulation, for example, on a patient model by including properties typical of tissue, such as conductivity, dielectricity, and density.

The global radio-frequency load on the patient is initially calculated in advance during the planning of the radio-frequency pulses to be output, and the radio-frequency pulses are selected so that a specific threshold is not reached. In such cases, the radio-frequency load is to be understood below as a physiological load induced by the RF radiation and not the RF energy introduced as such. A typical measure of the radio-frequency load is the specific absorption rate (SAR), which specifies in watt/kg the biological load that acts on the patient through a specific radio-frequency pulse power. For the global SAR or RF load of the patient, a standardized threshold, for example, applies of 4 watt/kg at the “first Level” according to the IEC standard. A further typical measure is the specific energy dose (SED). It is known that an SAR value may be converted into an SED value and vice versa.

In addition, as well as in advance planning, the SAR load on the patient is continuously monitored during the examination by suitable safety devices on the magnetic resonance system, and a measurement is changed or aborted if the SAR value lies above the intended standards. The most exact advance planning possible is sensible in order to avoid a measurement being aborted, since this would make a new measurement necessary.

Multichannel pulse trains may be generated in advance for a specific planned measurement. For this purpose, in an optimization method, the individual RF pulse trains (e.g., the RF trajectories) are determined for the individual transmit channels over time depending on a “transmit k-space trajectory,” for example, which may be prespecified by a measurement protocol. The “transmit k-space gradient trajectory” (e.g., “k-space trajectory”) involves the locations in the k-space to which there is movement by setting the individual gradient at specific times (e.g., by coordinated gradient pulse trains to be transmitted (with matching x, y and z gradient pulses)) to be transmitted coordinated with the RF pulse trains. The k-space is the local frequency space, and the gradient trajectory in the k-space describes the path on which the k-space is passed through in time by transmission of an RF pulse or the parallel pulses by corresponding switching of the gradient pulses. By adjusting the gradient trajectory in the k-space (e.g., by adjusting the appropriate gradient trajectory applied in parallel to the multichannel pulse train), the local frequencies at which specific RF energies are deposited may be determined in this way.

There are also multichannel pulse trains that are not formed by departing from the k-space. These include the “composite pulses”, radio-frequency pulses that are displayed after each other.

The optimization method for determining amplitudes and phases of the radio-frequency pulses operates, like every optimization method, with a predetermined target function. For the planning of the RF pulse sequence, the user specifies a target magnetization (e.g., a desired flip angle distribution in a specific space) that is used within the target function as the setpoint value. In the optimization program, the appropriate RF pulse sequence for the individual channels is then calculated for the predetermined target function, so that the target magnetization is achieved. A method for developing such multichannel pulse trains in parallel excitation methods is described, for example, in W. Grishom et al.: “Spatial Domain Method for the Design of RF Pulses in Multicoil Parallel Excitation”, Mag. Res. Med. 56, 620-629, 2006. This method however only applies for linear approximation.

For a specific measurement, the different multichannel pulse trains, the gradient pulse trains belonging to the respective control sequence and further control specifications are defined in a so-called measurement protocol that is created beforehand and is retrieved for a specific measurement, for example, from a memory and may be modified if necessary by an operator on site. During the measurement, the magnetic resonance system is controlled fully automatically on the basis of this measurement protocol. The control device of the magnetic resonance system reads out the commands from the measurement protocol and processes the commands.

The basis of the planning of the RF pulses, for which the user specifies a target magnetization, is the Bloch equation

$$\frac{d M}{d t} = γ \cdot M \times B \qquad ( 1 )$$

which describes the magnetization built up by a magnetization vector M in a magnetic field B. γ is the gyromagnetic ratio of the core to be excited (e.g., for normally excited hydrogen, γ=42, 58 MHz/T).

In the optimization method, a desired locally-resolved flip angle distribution, which is used within the target function as the setpoint value, is predetermined, for example. The appropriate RF pulses for the individual channels are calculated so that the target magnetization is achieved as well as possible. The Bloch equation involves a differential equation. In the optimization method, therefore, a non-linear equation system would be solved. Each volume unit (e.g., volume element (voxel) observed in the field of view) stands for one equation and each discrete time step is to be calculated. Non-linear solvers may be used for this (e.g., computer programs that may solve systems of non-linear equations). With the scope of the equation system presented, the non-linear solvers provide a significant computing effort.

The optimization method may therefore initially be carried out for a lower target magnetization. A lower target magnetization provides reaching a smaller flip angle. This allows the Bloch equation (1) to be replaced by a linear approximation. For this procedure, for small magnetizations (e.g., for smaller flip angles in the “low-flip area” such as between 0 and 5°), the magnetization behavior is still linear. Therefore, a calculation with an optimization method in this area is significantly easier and more stable. For small flip angles the Bloch equation produces a linear equation system

A·b=m_{des} (2)

In this equation, m_{des} stands for the vector of the spatially discretized target magnetization, the vector b stands for the temporal discretization of the RF pulses, and A is a matrix that includes the linear relationships produced by the discretization of the linearized solution of the Bloch equations between the vector m_{des} and the vector b.

The multichannel pulse train determined with this method is subsequently scaled up to a final target magnetization. If, for example, the calculation in the low flip area is made for a flip angle of maximum α=5°, and the actual magnetization is to take place with a flip angle α of maximum 90° in accordance with the ratio of the flip angles, the amplitude values of the RF pulses may be multiplied by a factor of 18.

The problem with this method of operation is that errors that are to be compensated for later arise as a result of the upscaling. With a few newer pulses such as the “composite pulses,” for example, a linearization leads to completely incorrect results or is simply not able to be applied. Thus, there are pulses with which non-linear effects may be utilized entirely intentionally. For these pulses, a linear approximation is provided right from the start.

To reach the target magnetization precisely (e.g., to achieve a high quality of the magnetization with large flip angles of 90° in the range of 180°), the optimization method may be carried out based on the Bloch equation. For the pulses mentioned above, which make use of non-linear effects, the Bloch equation is used in any event.

At the same time, precisely with large flip angles, managing the radio-frequency load (e.g., the radio-frequency load in all voxels of the field of view (FOV)) is important for all types of pulse.

Previously, direct account was taken of the local radio-frequency load only for a linear pulse calculation. For a calculation of the pulses using the Bloch equation, the local radio-frequency load may only be defined independently of the pulse calculation. If the threshold values are exceeded, the entire pulse calculation is to be started again.

### SUMMARY AND DESCRIPTION

The present embodiments may obviate one or more of the drawbacks or limitations in the limitations in the related art. For example, a suitable method and a corresponding control sequence determination device for determining magnetic resonance system control sequences, which provide a reduction and/or secure ability to check a local radio-frequency load on a patient even during the development of the multichannel pulse trains with less calculation time and better achievement of the target magnetization, even at large flip angles are provided.

In one embodiment of a method, based on a pre-determined target function with a predetermined target magnetization, a multichannel pulse train is calculated in an RF pulse optimization method.

In this process, the RF pulse optimization method takes account of a magnetization in the form of the non-linear Bloch equation and a local radio-frequency load in a plurality of volume elements in the form of quadratic equation systems.

A local RF load in this case is not to be understood as the RF amplitude occurring at a location or in a specific volume element, but as the energy load resulting therefrom or as the physiological load induced by the RF radiation (e.g., in the form of a specific energy dose (SED) value or of a specific absorption rate (SAR) value in a specific local volume (e.g., at one or more hotspots).

By taking account of the magnetization in the form of the non-linear Bloch equation (1), a high accuracy is achieved even at large flip angles. There is no need for any rectification after the upscaling for a calculation in the linearized form. Even the newer composite pulses that make use of non-linearities are able to be calculated with this method.

By simultaneously taking account of the local radio-frequency load in a plurality of volume elements in the form of quadratic equation systems, the optimization is carried out simultaneously for both target specifications: A highest possible quality of the magnetization (e.g., reaching the target magnetization as accurately as possible) and a local radio-frequency load lying below the permissible threshold values.

One embodiment of a control sequence determination device has an input interface for detecting a target magnetization, an RF pulse optimization unit in order, on the basis of a predetermined target function with a predetermined target magnetization, to calculate a multichannel pulse train in an RF pulse optimization method, and a control sequence output interface in order to transfer the control sequence for controlling the magnetic resonance system for data acquisition to a control device or to store the control sequence for this purpose in a memory. The control sequence determination device is configured to take account of a magnetization in the form of the non-linear Bloch equation and a local radio frequency load (SAR) in a plurality of volume elements in the form of quadratic equation systems in the RF pulse optimization method.

In one embodiment of a method for operation of a magnetic resonance system, a control sequence is determined, and the magnetic resonance system is operated using this control sequence. Accordingly, a magnetic resonance system includes a previously described control sequence determination device.

Major parts of the control sequence determination device may be configured in the form of software components and/or hardware components (e.g., a processor). This relates to the RF pulse optimization unit and, if necessary, also—as will be explained again later—to a specific RF load optimization unit. The input interface may, for example, include a user interface for manual entry of a target magnetization (e.g., also a graphical user interface). In this case, the input interface may also include an interface for selecting and accepting data (e.g., also a suitable target function) from a data memory disposed within the control sequence determination device or connected over a network to the control sequence determination device (e.g., also using the user interface). The control sequence output interfaces may, for example, include interfaces that transfer the control sequence to a magnetic resonance controller in order to control the measurements directly by doing so, but may also include an interface that sends the data over a network and/or stores the data in a memory for later use. These interfaces may be configured at least partly in the form of software and may have access to hardware interfaces of an available computer.

A computer program that is able to be loaded directly into a non-transitory computer readable storage medium (e.g., a memory) of a control sequence determination device includes program code sections (e.g., instructions) executable by one or more programmable processors in order to carry out all acts of the method. Such a software realization has the advantage that even previous devices that are used for determination of control sequences (e.g., suitable computers in computer centers of the magnetic resonance system manufacturers) may be modified by implementing the program in a suitable manner in order to determine control sequences, which are connected to a smaller and/or more safely-controllable radio-frequency load.

The description of one category may also be further developed in a similar way to the description of another claim category.

The local radio-frequency load is different at different locations in the body of the object under examination. Hotspots at which especially high RF loads (e.g., RF-induced physiological loads) occur will form.

In one embodiment, the RF pulse optimization method determines amplitude and phase of the RF pulse trains to be sent out in parallel by minimizing the sum that is formed from a deviation of a magnetization achieved from the predetermined target magnetization and the local RF load. This may be expressed by the following equation (3):

$${min}_{A , phi} ( {‖ M ( A , phi ) - {M}_{des} ‖}_{2} + ( {\sum }_{n = 1 … N} ( {\sum }_{t = 1 … T} {U}_{t}^{T} {V}_{n} {U}_{t} ) ) ) \qquad ( 3 )$$

The first summand: ∥M(A,phi)−M_{des}∥₂ calculates the deviation of the magnetization M(A,phi) achieved from the target magnetization M_{des}. In this equation, A is the amplitude, and phi is the phase of the radio-frequency pulses. The magnetization is dependent on amplitude and phase.

The second summand:

$${\sum }_{n = 1 … N} ( {\sum }_{t = 1 … T} {U}_{t}^{T} {V}_{n} {U}_{t} )$$

calculates the local RF load in the form of a quadratic equation. In this equation, Uₜ is a vector with the voltages or amplitudes of the radio-frequency pulses at discrete time step t, where the vector includes one element per transmit channel. Uₜ^{T} is the transposed vector for this. Vₙ is the sensitivity matrix (e.g., a matrix Vₙ exists for each volume element examined). The elements of the sensitivity matrix Vₙ represent the E field of the volume element concerned. A summing is carried out over time with the time steps t from 1 to T and a summing over the volume elements n from 1 to N.

Equation (3) shows that both specifications (e.g., the magnetization and the radio-frequency load) are calculated in the same optimization process. The two conditions are contrary to one another. The best achievement of the target magnetization may be reached if the radio-frequency load is ignored. The lowest radio-frequency load may be achieved if the target magnetization is not reached.

In one embodiment, the amount of the local RF load is therefore weighted. This is expressed by a weighting factor λ in equation (4), which otherwise corresponds to equation (3):

$${min}_{A , phi} ( {‖ M ( A , phi ) - {M}_{des} ‖}_{2} + λ ( {\sum }_{n = 1 … N} ( {\sum }_{t = 1 … T} {U}_{t}^{T} {V}_{n} {U}_{t} ) ) ) \qquad ( 4 )$$

The choice of the weighting factor λ enables the weighting factor λ to be defined even during the design of the RF pulses whether, for a better quality of the magnetization (e.g., a more accurate achievement of the target function), a higher radio-frequency load (e.g., always within the framework of statutory protection legislation) is taken into account. In this case, λ is reduced. Alternatively, greater account is taken of the radio-frequency load (e.g., λ is increased, and a greater deviation of the magnetization from the target magnetization is taken into account).

In one embodiment, the value of the local RF load is squared, as shown in the equation (5) below, which otherwise corresponds to equation (4).

$${min}_{A , phi} ( {‖ M ( A , phi ) - {M}_{des} ‖}_{2} + λ ( {\sum }_{n = 1 … N} {( {\sum }_{t = 1 … T} {U}_{t}^{T} {V}_{n} {U}_{t} )}^{2} ) ) \qquad ( 5 )$$

A squaring may also be provided without the weighting factor X, in accordance with equation (4). A squaring is one option of disproportionately weighting large local SAR values. Other weightings may also be provided.

In one embodiment, the RF pulse optimization method takes account of the local RF load essentially only in selected volume elements (voxels) or in virtual volume elements. The use of selected volume elements may also be combined with the use of virtual volume elements. The computing effort is reduced if not every volume element has to be checked for the radio-frequency load. The value N in equations (3) to (5) is thus reduced.

A suitable choice of the voxels taken into consideration provides that all hotspots are still detected. A selection method may, for example, take account of the patient model. The different tissue structures in the human body may be used as a basis. In the equations (3) to (5), the second summand is then only to be defined for the selected voxels.

Virtual volume elements may, for example, be created by compression methods. To do this, in a first act, a computer model is created in the known way for the coil that is used. In a second act, in a known way, a computer model of a patient is created. The patient model is shifted in the next act virtually into the antenna field and virtually exposed to the electrical fields. A simulation takes place. From this, electrical field data is produced for all examined volume elements of the patient. This volume element data may be compressed in a compression act so that for all possible phase angles of the radio-frequency fields of the antennas, the compressed voxel data safely contains the highest radio-frequency loads occurring. The compression method does not take account of the physiological properties of the patient or of the patient model.

Thus, a set of virtual voxels that do not really exist, which contains the same information as all the voxels contained in the model, is obtained.

In one embodiment, the virtual voxels are known as Virtual Observation Points (VOP), as are described, for example, in G. Eichfelder et al.: “Local Specific Absorption Rate Control for Parallel Transmission by Virtual Observation Points”, Mag. Res. Med. 66, 1468-1476, 2011. The Virtual observation points are determined based on abstract group formation criteria. The virtual voxels in entirety include all possible hotspots. Thus, a reduction from a few million voxels to a few hundred virtual observation points is achieved, which greatly simplifies taking account of the second summand.

In one embodiment, the RF pulse optimization method takes account of the magnetization in the form of the non-linear Bloch equation essentially for all volume elements within a field of view. In the equations (3) to (5), the first summand is to be formed for all voxels in the field of view and for all discrete time steps. The accuracy of the determination of the magnetization, even for large flip angles, is thus guaranteed.

In an embodiment, one of the following methods is used in the RF pulse optimization method: Gradient descent method; Newton method; and Levenberg-Marquardt method.

In the gradient descent method, the initial starting point is an approximation value, and the method then steps in the direction of the steepest descent away from the approximation value until no further numeric improvement is achieved.

The Newton method is a mathematical standard method for solving non-linear equation systems.

The Levenberg-Marquardt method, as a numerical optimization process, applies the method of least mean squares.

Other methods may also be used.

In one embodiment, the multichannel pulse train includes a pulse sequence with a number of consecutive slice-selective pulses. These involve composite pulses, for example, that create high flip angles and may only be described with the non-approximated Bloch equations.

### BRIEF DESCRIPTION OF THE DRAWINGS

FIG. 1 shows a schematic diagram of an exemplary embodiment of a magnetic resonance system;

FIG. 2 shows a flowchart for a possible sequence in accordance with an exemplary embodiment of a method;

FIG. 3 shows a graph of exemplary curves that represent a local peak radio-frequency load value as a function of an average quadratic deviation of a flip angle for composite pulses, using a global and a local radio-frequency load value; and

FIG. 4 shows a graph of exemplary curves that represent a local peak radio-frequency loading value as a function of the average quadratic deviation of the flip angle for spoke pulses, using a global and a local radio-frequency load value.

### DETAILED DESCRIPTION

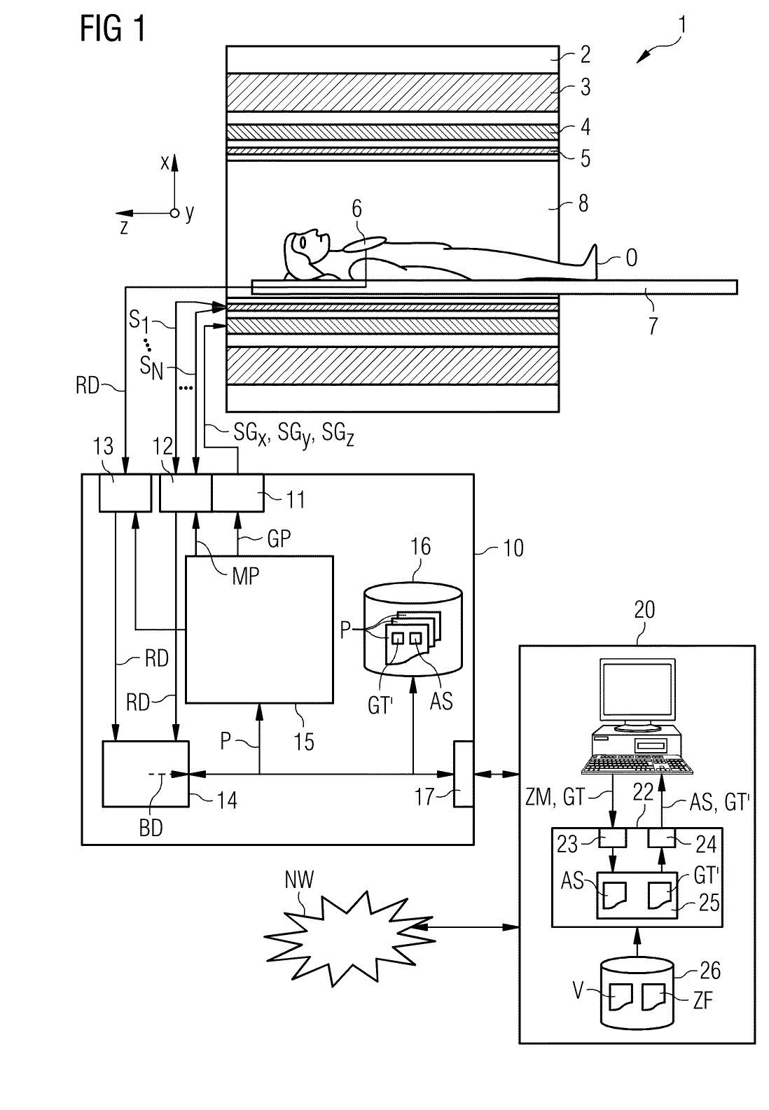

FIG. 1 shows an outline schematic diagram of one embodiment of a magnetic resonance system 1. The magnetic resonance system 1 includes an actual magnetic resonance scanner 2 with an examination space 8 or patient tunnel 8 located in the actual magnetic resonance scanner 2. A couch 7 is able to be moved into this patient tunnel 8 so that a patient O or sample lying on the couch 7 may be supported during an examination at a specific position within the magnetic resonance scanner 2 relative to the magnet system and radio-frequency system disposed therein or is also able to be moved during a measurement between different positions.

Components of the magnetic resonance scanner 2 are a basic field magnet 3, a gradient system 4 with magnet field gradient coils in order to apply magnetic field gradients in the x, y and z direction, and a radio-frequency whole body coil 5. Magnetic resonance signals induced in the object under examination O may be received via the whole body coil 5, with which the radio-frequency signals may also be transmitted to induce the magnetic resonance signals. These signals may be received by local coils 6 disposed on or under the object under examination O. All these components are basically known to the person skilled in the art and therefore are only shown as rough schematics in FIG. 1.

The radio-frequency whole body coil 5 is constructed in the form of, for example, a birdcage antenna and has a number N of individual antenna rods that run in parallel to the patient tunnel 8 and are disposed evenly around a circumference of the patient tunnel 8. At an end side the individual antenna rods are each connected capacitively in the shape of a ring.

The individual antenna rods are able to be controlled, for example, as individual transmit channels S₁, . . . , S_{N} separately by a control device 10 (e.g., a controller). The controller 10 may include a control processor that may also include a plurality of individual processors (e.g., if necessary, also spatially separated and connected to each other via suitable cables or the like). This controller 10 is linked via a terminal interface 17 to a terminal 20, via which an operator may control the entire system 1. The terminal 20 is equipped as a computer with keyboard, display screens and also further input devices such as a mouse or the like, for example, so that a graphical user interface is available to the operator.

The controller 10 includes, for example, a gradient control unit 11 that may include a number of subcomponents. Via this gradient control unit 11, control signals SGₓ, SG_{y}, SG_{z} are switched to the individual gradient coils. This involves gradient pulses that are set during a measurement at precisely provided temporal positions and with a precisely predetermined timing sequence.

The controller 10 also has a radio-frequency transceiver unit 12. This RF transceiver unit 12 also includes a number of subcomponents that each separately and in parallel emit radio-frequency pulses on the individual transmit channels S₁, . . . S_{N} (e.g., on the individually-controllable antenna rods of the whole body coil). Magnetic resonance signals may also be received via the transceiver unit 12. This may be done with the aid of the local coils 6. The raw data RD received with the local coils 6 is read out and processed by an RF receive unit 13. The magnetic resonance signals received by this unit or by the whole body coil by the RF transceiver unit 12 are transferred as raw data RD to a reconstruction unit 14 that reconstructs the image data BD from the data and stores the reconstructed image data BD in a memory 16 and/or transfers the reconstructed image data BD via the interface 17 to the terminal 20, so that the operator may view the reconstructed image data BD. The image data BD may also be stored and/or displayed and evaluated via a network NW at other locations.

The gradient control unit 11, the radio-frequency transceiver unit 12 and the receive unit 13 for the local coils 6 are each controlled in a coordinated manner by a measurement control unit 15. This also provides, through appropriate commands, that a desired gradient pulse train GP is emitted by suitable gradient control signals SGₓ, SG_{y}, SG_{z}, and the RF transceiver unit 12 is controlled in parallel so that a multichannel pulse train MP is sent out (e.g., that the appropriate radio-frequency pulses are emitted on the individual transmit channels S₁, . . . S_{N} in parallel to the individual transmit rods of the whole body coil 5). In addition, at the appropriate time, the magnetic resonance signals at the local coils 6 or signals to the whole body coil 5 by the RF transceiver unit 12 are read out and further processed by the RF receiver unit 13. The measurement control unit 15 specifies the corresponding signals (e.g., the multichannel pulse train MP) to the radio-frequency transceiver unit 12 and the gradient pulse train GP to the gradient control unit 11 in accordance with a predetermined control protocol P. All control data that is to be set during a measurement is held in this control protocol P.

A plurality of control protocols P for different measurements may be held in a memory 16. The plurality of control protocols P may be selected by the operator via the terminal 20 and varied, if necessary, in order to have an appropriate control protocol P, with which the measurement control unit 15 may operate, available for the current desired measurement. In addition, the operator may also retrieve control protocols P over a network NW, for example, from a manufacturer of the magnetic resonance system 1, and may then modify and use the control protocols P if necessary.

The underlying execution sequence of such a magnetic resonance measurement and the known components for control are however known to the person skilled in the art, and are not described in any further detail. In addition, such a magnetic resonance scanner 2 and the associated control device 10 may also have a plurality of further components that are likewise not described in detail.

The magnetic resonance scanner 2 may also be constructed differently, for example, with a patient tunnel open to the side. The radio-frequency whole body coil may not be constructed as a birdcage antenna. The magnetic resonance scanner 2 has a number of separately controllable transmit channels S₁, . . . , S_{N}. Accordingly, in the control device 10, a corresponding number of channel controllers is also made available by the radio-frequency transceiver device to enable the individual transmit channels S₁, . . . , S_{N} to be controlled separately.

FIG. 1 shows one embodiment of a control sequence determination device 22. The control sequence determination device 22 is used for determination of a magnetic resonance system control sequence AS. This magnetic resonance system control sequence AS includes, for example, items such as a predefined multichannel pulse train MP for a specific measurement for controlling the individual transmit channels S₁, . . . , S_{N}. The magnetic resonance system control sequence AS is created as part of the measurement protocol P.

The control sequence determination device 22 is shown in FIG. 1 as part of the terminal 20 and may be realized in the form of software components on the processor of the terminal 21. The control sequence determination device 22 may also be part of the control device 10 or be realized on a separate computer system, and the finished control sequences AS (e.g., if necessary, also within the framework of a complete control protocol P) are transferred over a network NW to the magnetic resonance system 1.

The control sequence determination device 22 has an input interface 23. Via this input interface 23, the control sequence determination device 22 receives a target magnetization ZM that specifies how the flip angle distribution is to be for the desired measurement. In addition, a k-space gradient trajectory GT may be predetermined for the desired pulse sequence.

Both specifications are made, for example, by an expert with the appropriate expertise in developing control protocols for specific measurements. The data thus obtained is transferred to an RF pulse optimization unit 25 that automatically creates a specific control sequence AS with an optimum multichannel pulse train MP for achieving the desired target magnetization ZM.

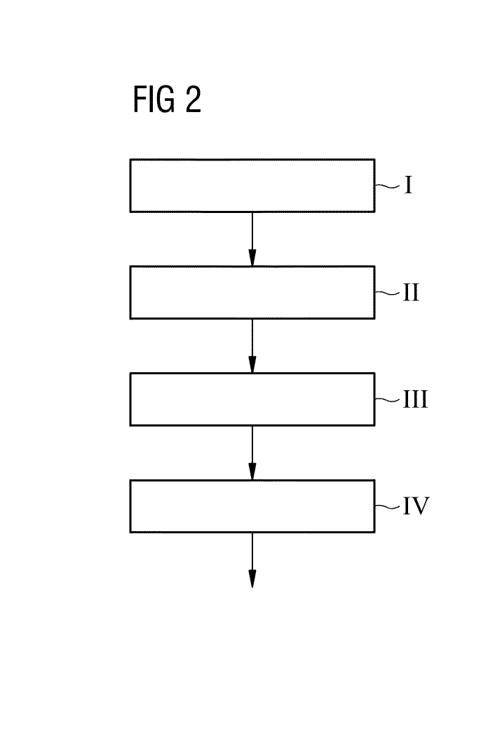

The execution sequence of such a method for determining a magnetic resonance system control sequence AS is explained below on the basis of the flow diagram depicted in FIG. 2 using a very simple example.

In act I, the target magnetization ZM and a gradient trajectory GT are predetermined. This provides that a gradient pulse sequence for following this gradient trajectory GT is defined. Depending on the desired pulse sequence, a gradient trajectory GT is not always necessary.

In act II, the selected volume elements for which a local radio-frequency load is to be calculated and is to be determined in the optimization method are defined. In one embodiment, virtual observation points are determined in accordance with a mathematical concept. For this purpose, a model of the transmit coil used in the magnetic resonance system and a model of a person or patient is first needed. In this case, there is the balancing between a smallest possible number of virtual observation points which reduces the computing effort and a determination of the maximum radio-frequency load occurring at a hotspot without defining this conservatively. If more VOPs are used, the overestimation of the local SAR is smaller, which allows a higher RF load within the standard. A higher radio-frequency load improves the image quality (e.g., a more precise achievement of the target magnetization).

Each virtual observation point is described by a sensitivity matrix V. The sensitivity matrix V includes a sensitivity value for each transmit channel and each time step. The sensitivity value, multiplied by the amplitude of the RF field, describes the E field in the virtual observation point involved and thus forms a conversion factor from the amplitude of the radio-frequency curve to the actual energy load in the virtual observation point.

The sensitivity matrix V and the target function may, for example, be held in a memory 26 of the control sequence determination device 22 and may be retrieved from the memory 26 if required. The sensitivity matrix may be determined, for example, in advance by simulations on body models. A method for determining such a sensitivity matrix and the local SED values SED_{loc,h} is described, for example, in DE 10 2009 024 077, the contents of which are hereby fully incorporated by reference in this regard. In such cases, different sensitivity matrixes may also be stored for different body types (e.g., different sizes of patient).

In act III, the Bloch equation is set up for each voxel to enable the achievable magnetization M(A, phi) to be determined as a function of amplitude and phase of the individual radio-frequency signals.

In act IV, the pulse trains to be sent out by the individual send antennas are determined in accordance with amplitude and phase. At the same time, the deviation of the magnetization achieved from the target magnetization is minimized, and the local radio-frequency load is minimized in accordance with equation (6). A non-linear solver is employed for this purpose.

Since the Bloch equations involve a differential equation system, the Jakobi matrix is used. This allows the derivation of an equation system with many variables. The number of equation systems to be solved is given, for example, by the number of the volume elements (voxels). The number of variables is produced from the number of time steps multiplied by the number of transmit channels multiplied by the factor 2, since complex variables with amplitude and phase are involved. With, for example, 4000 voxels per magnetized slice, 3 to 200 time steps and 8 channels, 4000 equation systems each with up to 3200 variables are produced. These values are to be understood purely by way of example and not limiting. These values merely give an idea of the extent of the equation system to be solved.

With the quadratic equation system for minimization of the local radio-frequency load, around 1000 virtual observation points are taken into account. This number too is purely by way of example.

In the equation system set up and solved by the optimization method, all sensitivity matrices for all virtual observation points are taken into account simultaneously. An iterative method is not necessary. The maximum local SAR value may also be minimized for such pulses, which may produce a high flip angle. These pulses include composite pulses and spoke pulses.

Depending on the application, precedence may be given during optimization to the quality of the magnetization or to minimizing the radio-frequency load by setting a weighting factor.

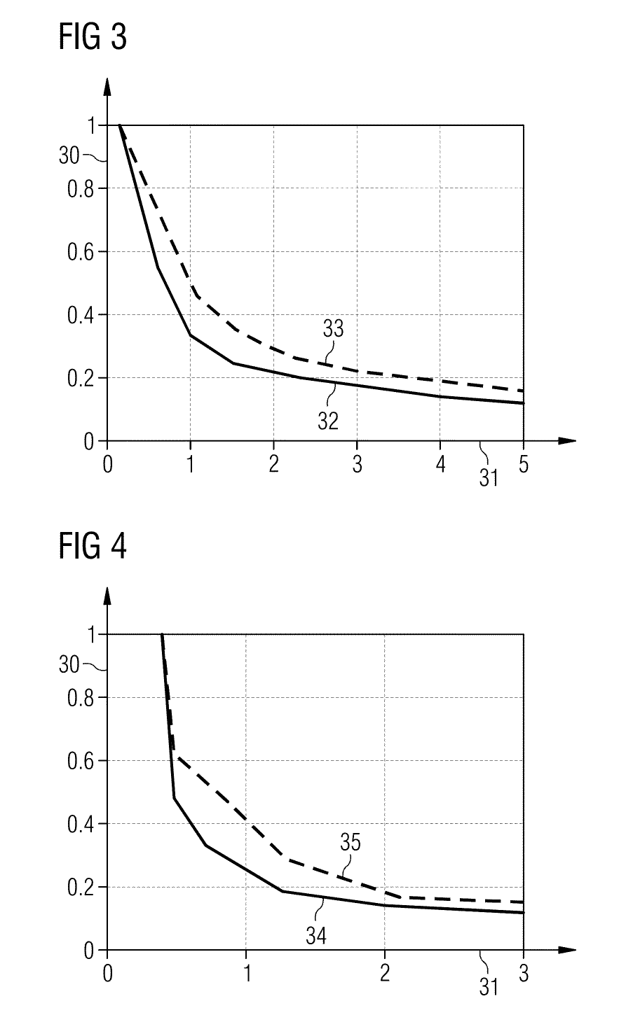

The advantages of the method of one or more of the present embodiments are clearly illustrated below with reference to FIGS. 3 and 4.

In FIG. 3, a local peak radio-frequency pulse energy is plotted on an axis 30 in any given units against an axis 31 with the average quadratic deviation of the flip angle from a setpoint value in degrees. Curve 32 shows a graph for a composite pulse that is composed of three subpulses, for an optimization (e.g., when taking account of the local radio-frequency load during the optimization). Curve 33 likewise shows a graph for the composite pulse that, for an optimization, only takes account of a global radio frequency load during the optimization. The overall pulse in each case has an overall duration of, for example, around 3 ms.

If in the equation (5) a weighting is undertaken such that the weighting factor λ is set to zero (e.g., no minimization of the radio-frequency load takes place), then the curves 32 and 33 in FIG. 3 come together on the left-hand side of the graph. The deviation of the flip angle achieved from the predetermined flip angle then approaches zero. For all weighting factors λ greater than zero curve 32 lies below curve 33, the radio frequency load is lower for the same deviation of the achieved flip angle from the predetermined flip angle. A reduction of up to 20% of the local radio-frequency load has been achieved for the same accuracy of magnetization.

In FIG. 4, a local peak radio-frequency pulse energy is plotted on an axis 30 in any given units against an axis 31 with the average quadratic deviation of the flip angle from a setpoint value in degrees. Curve 34 shows a graph for a spoke pulse, which is composed of three spokes, for an optimization (e.g., when taking into account the local radio-frequency load during the optimization). Curve 35 likewise shows a graph for the spoke pulse for an optimization that merely takes account of a global radio-frequency load during the optimization. The overall pulse in each case has an overall duration of around 3 ms.

As in FIG. 4, the curves 34 and 35 come together when the weighting factor λ is set to zero (e.g., there is no minimization of the radio-frequency load). The deviation of the flip angle achieved from the predetermined flip angle then approaches zero.

For all weighting factors λ greater than zero curve 34 lies below curve 35, the radio-frequency load is lower for the same deviation of the flip angle achieved from the predetermined flip angle. A reduction of up to 30% of the local radio-frequency load has been achieved for the same accuracy of magnetization.

The checking calculation taking into account the global radio-frequency load is also already undertaken with the complete Bloch equations without an approximation by linearization.

The detailed methods and structures previously described involve exemplary embodiments, and the basic principle may also be varied by the person skilled in the art in other areas without departing from the field of the invention, provided it is specified by the claims. The use of the indefinite article “a” or “an” does not exclude the features involved also being able to be present multiple times. Likewise the term “unit” does not preclude the unit including a number of components that may likewise also be spatially distributed.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A method for determining a magnetic resonance system control sequence, the magnetic resonance system control sequence comprising a multichannel pulse train with a plurality of individual RF pulse trains to be sent out in parallel by a magnetic resonance system via different independent radio-frequency transmit channels, the method comprising:
calculating the multichannel pulse train in an RF pulse optimization based on a predetermined target function with a predetermined target magnetization,
wherein the RF pulse optimization takes account of a magnetization in the form of a non-linear Bloch equation and of a local radio-frequency load in a plurality of volume elements in the form of quadratic equation systems.

2. The method as claimed in claim 1, further comprising determining, with the RF pulse optimization, amplitude and phase of the plurality of RF pulse trains to be sent out in parallel, the determining comprising minimizing a sum that is formed from a deviation of an achieved magnetization from the predetermined target magnetization and the local radio-frequency load.

3. The method as claimed in claim 1, wherein an amount of the local radio-frequency load is weighted.

4. The method as claimed in claim 1, wherein a value of the local radio-frequency load is squared.

5. The method as claimed in claim 1, wherein the RF pulse optimization takes account of the local radio-frequency load essentially only in selected volume elements, virtual volume elements, or selected and virtual volume elements.

6. The method as claimed in claim 5, wherein the RF pulse optimization takes account of the local radio-frequency load essentially only in the virtual volume elements or the selected and virtual volume elements, and
wherein the virtual volume elements are virtual observation points.

7. The method as claimed in claim 1, wherein the RF pulse optimization takes account of the magnetization in the form of the non-linear Bloch equation essentially for all volume elements within a field of view.

8. The method as claimed in claim 1, wherein the RF pulse optimization comprises a gradient descent method, a Newton method, or a Levenberg-Marquardt method.

9. The method as claimed in claim 1, wherein the multichannel pulse train comprises a pulse sequence with a plurality of consecutive slice-selective pulses.

10. A method for operating a magnetic resonance system with a plurality of independent radio-frequency transmit channels, the method comprising:
determining a control sequence, the control sequence comprising a multichannel pulse train with a plurality of individual RF pulse trains to be sent out in parallel by the magnetic resonance system via different independent radio-frequency transmit channels, the determining comprising:
calculating the multichannel pulse train in an RF pulse optimization based on a predetermined target function with a predetermined target magnetization, wherein the RF pulse optimization takes account of a magnetization in the form of a non-linear Bloch equation and of a local radio-frequency load in a plurality of volume elements in the form of quadratic equation systems; and
operating the magnetic resonance system using this control sequence.

11. A control sequence determination device for determining a magnetic resonance system control sequence, the magnetic resonance system control sequence comprising a multichannel pulse train with a plurality of individual RF pulse trains to be sent out in parallel by a magnetic resonance system over different independent radio-frequency transmit channels, the control sequence determination device comprising:
an input interface configured to capture a target magnetization;
an RF pulse optimization unit configured to calculate the multichannel pulse train based on a predetermined target function with a predetermined target magnetization, in an RF pulse optimization; and
a control sequence output interface,
wherein the control sequence determination device is configured such that, in the RF optimization, the control sequence determination device takes account of a magnetization in the form of a non-linear Bloch equation and takes account of a local radio-frequency load in a plurality of volume elements in the form of quadratic equation systems.

12. A magnetic resonance system comprising:
a plurality of independent radio-frequency transmit channels;
a gradient system;
a control device configured to carry out a desired measurement based on a control sequence that is predetermined, to send out a multichannel pulse train with a plurality of parallel individual RF pulse trains via the plurality of radio-frequency transmit channels; and
a control sequence determination device for determining the control sequence, the control sequence comprising the multichannel pulse train with the plurality of individual RF pulse trains to be sent out in parallel by the magnetic resonance system the plurality of radio-frequency transmit channels, the control sequence determination device comprising:
an input interface configured to capture a target magnetization;
an RF pulse optimization unit configured to calculate the multichannel pulse train based on a predetermined target function with a predetermined target magnetization, in an RF pulse optimization; and
a control sequence output interface,
wherein the control sequence determination device is configured such that, in the RF optimization, the control sequence determination device takes account of a magnetization in the form of a non-linear Bloch equation and takes account of a local radio-frequency load in a plurality of volume elements in the form of quadratic equation systems, and
wherein the control sequence determination device is configured to transfer the determined control sequence to the control device.

13. In a non-transitory computer readable storage medium having stored therein data representing instructions executable by a programmed processor of a control sequence determination device for determining a magnetic resonance system control sequence, the magnetic resonance system control sequence comprising a multichannel pulse train with a plurality of individual RF pulse trains to be sent out in parallel by a magnetic resonance system via different independent radio-frequency transmit channels, the instructions comprising:
calculating the multichannel pulse train in an RF pulse optimization based on a predetermined target function with a predetermined target magnetization,
wherein the RF pulse optimization takes account of a magnetization in the form of a non-linear Bloch equation and of a local radio-frequency load in a plurality of volume elements in the form of quadratic equation systems.

14. The non-transitory computer readable storage medium as claimed in claim 13, wherein the instructions further comprise determining, with the RF pulse optimization, amplitude and phase of the plurality of RF pulse trains to be sent out in parallel, the determining comprising minimizing a sum that is formed from a deviation of an achieved magnetization from the predetermined target magnetization and the local radio-frequency load.

15. The non-transitory computer readable storage medium as claimed in claim 13, wherein an amount of the local radio-frequency load is weighted.

16. The non-transitory computer readable storage medium as claimed in claim 13, wherein a value of the local radio-frequency load is squared.

17. The non-transitory computer readable storage medium as claimed in claim 13, wherein the RF pulse optimization takes account of the local radio-frequency load essentially only in selected volume elements, virtual volume elements, or selected and virtual volume elements.

18. The non-transitory computer readable storage medium as claimed in claim 17, wherein the RF pulse optimization takes account of the local radio-frequency load essentially only in the virtual volume elements or the selected and virtual volume elements, and
wherein the virtual volume elements are virtual observation points.

19. The non-transitory computer readable storage medium as claimed in claim 13, wherein the RF pulse optimization takes account of the magnetization in the form of the non-linear Bloch equation essentially for all volume elements within a field of view.

20. The non-transitory computer readable storage medium as claimed in claim 13, wherein the RF pulse optimization comprises a gradient descent method, a Newton method, or a Levenberg-Marquardt method.
